(19) United States
(12) Patent Application Publication
(10) Pub. No.: US 2016/0340519 A1
(43) Pub. Date: Nov. 24, 2016

(54) CONDUCTIVE PASTE COMPOSITION, CONDUCTIVE STRUCTURE AND METHOD OF PRODUCING THE SAME

(71) Applicant: CHUAN HSI RESEARCH CO., LTD., Pingtung (TW)

(72) Inventors: Shu-Ching YANG, Pingtung (TW); Janet TSAO, Pingtung (TW)

(21) Appl. No.: 15/058,170

(22) Filed: Mar. 2, 2016

(30) Foreign Application Priority Data
May 22, 2015 (TW) 104116523

(51) Int. Cl. C09D 5/24; H01L 31/0224

(52) U.S. Cl. CPC C09D 5/24; H01L 31/022425

(57) ABSTRACT

A conductive paste composition is provided, and has a copper-containing conductive powder, an adhesive alloy powder selected from tin-based, bismuth-based, indium-based or zinc-based material, and an organic carrier. The organic carrier is 5-35% by weight of the conductive paste composition. Moreover, a method of producing a conductive structure is provided, and has steps of: applying the conductive paste composition onto the substrate to form a conductive pattern; heating the conductive pattern; and cooling the conductive pattern to obtain the conductive structure. The conductive pattern has a plurality of copper-containing conductive particles and an adhesive alloy. At least one part of the copper-containing conductive particles connects with each other through the adhesive alloy, and the copper-containing conductive particles are connected with the substrate by the adhesive alloy.

### CROSS REFERENCE TO RELATED APPLICATIONS

This application claims the benefit of priority of Taiwan Patent Application No. 104116523, filed on May 22, 2015, the disclosure of which is incorporated herein by reference.

### FIELD OF THE INVENTION

The present invention relates to a conductive paste composition, conductive structure and a method of producing a conductive structure, and in particular relates to a conductive structure capable of being formed at a lower temperature, a conductive paste composition used to form the conductive structure, and a method of producing the conductive structure.

### BACKGROUND OF THE INVENTION

Recently, because fossil fuel is gradually depleted, the development of various alternative energy resources (i.e. solar cell, fuel cells, and wind power) gets more and more attention, particularly the solar power generation.

A conventional solar cell assembled to a semiconductor structure having a connecting surface is shown in FIG. 1, which is a cross-sectional view of the conventional solar cell, wherein when forming the conventional solar cell element, firstly a p-type silicon semiconductor substrate 11 is provided which is etched to form the roughness of surface. Then, a light receiving side of the p-type silicon semiconductor substrate 11 is formed with an n-type diffusion layer 12 of reverse conductive type by heat diffusion using phosphorus or analogues, so as to form a p-n junction. Subsequently, an anti-reflection layer 13 and a front electrode 14 are formed on the n-type diffusion layer 12, wherein a silicon nitride layer is formed on the n-type diffusion layer 12 to be the anti-reflection layer 13 by plasma enhanced chemical vapor deposition (PECVD) thereof. Furthermore, the anti-reflection layer 13 is coated with silver conductive pastes by screen printing, and then processes of curing, drying, and high-temperature sintering are carried out to form the front electrode 14. In the process of high-temperature sintering, the silver conductive paste for forming the front electrode 14 can be sintered and penetrate the anti-reflection layer 13 until the silver conductive paste is electrically in contact with the n-type diffusion layer 12.

Furthermore, the back side of the p-type silicon semiconductor substrate 11 uses aluminum conductive paste to form a back electrode layer 15 of aluminum by printing. After, the processes of curing and drying are applied, and the process of high-temperature sintering is carried out, as described above. In the process of high-temperature sintering, the aluminum conductive paste is dried and converted into the back electrode layer 15 of aluminum. Simultaneously, the aluminum atoms are spread into the p-type silicon semiconductor material 11, so that there is a p+ layer 16 having a high concentration of aluminum dopant and formed between the back electrode layer 15 and p-type semiconductor material 11, which is usually called a back surface field (BSF) layer for improving the optical conversion efficiency of the solar cell. Because the back electrode layer 15 of aluminum is difficult to weld (poor wettability), the back electrode layer 15 is printed with an aluminum-silver conductive paste thereon by the screen printing, and then sintered to form a conductive wire 17 with good solderability, so that a plurality of solar cells can be serially connected to form a module.

However, the conventional solar cell elements still have the following problems: for example, the front electrode 14, the back electrode layer 15, and the connective wire 17 are made of silver, aluminum, or aluminum-silver conductive pastes. And, the material cost of these conductive pastes is high, and is about 10%-20% of the total cost of the module. Furthermore, the conductive pastes have a predetermined ratio of metal powders, glass powders and organic agents, for example, Japan Kokai Publication No. 2001-127317, Japan Sharp Publication No. 2004-146521, and Taiwan Pat. No. I339400 and I338308 issued to DuPond, wherein the conductive pastes contain glass microparticles that decrease the conductivity and solderability. Furthermore, the electrodes or conductive wires made by the conductive pastes must pass through the high-temperature sintering at 600-850° C. However, at the high temperature, the materials of others material layers may be deteriorated or malfunction, and even the yield of manufacturing the cells is seriously affected. As described above, according to the precise control requirement of the conditions of the high-temperature sintering, the process of high-temperature sintering needs to consume much time and has more complications, so as to affect the throughput per unit time when generating the cells.

Currently, the development trend in the solar cell industry is to reduce the material to lower the cost. Therefore, the solar cell wafer must be thinned from a thickness over 0.45 mm to a thickness less than 0.2 mm. However, the great thermal stress caused during the high temperature sintering process usually makes the thinned solar cell wafer warp or break. In addition, a cheaper copper may have the opportunity to replace the silver to become an electrode material in the solar cell. However, copper is very susceptible to oxidation in the atmosphere that causes the increased resistance and the copper cannot be combined with the solar cell wafer. Therefore, the copper needs to be sintered in a reducing atmosphere and the electrode is also easily oxidized in the subsequent uses. Thus, it still has limitations in the process conditions when the copper is used for replacing silver. The same problem also occurs on high power and high heat dissipation thin substrate LED, CPU, or a circuit pattern on a ceramic substrate used for IGBT configuration.

It is therefore necessary to provide a conductive paste composition which can be used to form a conductive structure at a low temperature in atmosphere, and reduce material costs, in order to solve the problems existing in the conventional technology as described above.

### SUMMARY OF THE INVENTION

A primary object of the present invention is to provide a conductive paste composition which can be used for producing a conductive structure at a temperature below 450° C., and contains no glass particles. The material costs can be reduced and the conductivity can be increased.

A secondary object of the present invention is to provide a method of producing a conductive structure by using the abovementioned conductive paste composition without protective atmosphere thereby the manufacturing process is simplified and the production costs is reduced.

A further object of the present invention is to provide a conductive structure which mainly contains copper-containing conductive powders without glass particles, and has superior conductivity.

A further object of the present invention is to provide a conductive structure having a conductive adhesive alloy used to connect the copper-containing conductive powders with each other, and to connect the copper-containing conductive powder and a substrate.

To achieve the above objects, the present invention provides a conductive paste composition, comprising: (a) a copper-containing conductive powder; (b) an adhesive alloy powder selected from a tin-based material, a bismuth-based material, an indium-based material or a zinc-based material; and (c) an organic carrier which is 5-35% by weight of the conductive paste composition.

Furthermore, the present invention provides a conductive structure which comprises a substrate; and a conductive pattern containing a plurality of copper-containing conductive particles and an adhesive alloy selected from a tin-based alloy, a bismuth-based alloy, an indium-based alloy or a zinc-based alloy, wherein at least one part of the copper-containing conductive particles connect with each other and the copper-containing conductive particles connect with the substrate through the adhesive alloy.

In one embodiment of the present invention, the copper-containing conductive powder comprises (1) Cu; and (2) one material selected from the group consisting of Ag, Ni, Al, Pt, Fe, Pd/Ru, Ir, Ti, Co, an Ag/Pd alloy, a copper-based alloy and a silver-based alloy, or a mixture of the material.

In one embodiment of the present invention, the copper-containing conductive powder further comprises at least one element selected from the group consisting of 0.1-12 wt % Si, 0.1-10 wt % Bi, 0.1-10 wt % In, 0.05-1 wt % P, and a mixture thereof.

In one embodiment of the present invention, the copper-containing conductive powder further comprises a protective layer selected from the group consisting of Au with a thickness ranged from 0.1 to 2 μm, Ag with a thickness ranged from 0.2 to 3 μm, Sn with a thickness ranged from 1 to 5 μm, Ni with a thickness ranged from 0.5 to 5 μm, a Ni/P alloy with a thickness ranged from 1 to 5 μm, a Ni—Pd—Au alloy with a thickness ranged from 1 to 3 μm and a combination thereof.

In one embodiment of the present invention, the adhesive alloy powder further comprises at least one bonding enhancement element selected from the group consisting of Ti, V, Zr, Hf, Nb, Ta, Mg, rare earth elements and a mixture thereof, and the bonding enhancement element is below 5 wt % of the adhesive alloy powder.

In one embodiment of the present invention, the rare earth elements is selected from the group consisting of Y, Sc, La series and a mixture thereof, and the rare earth elements has a weight percentage ranged from 0.1 to 1.5 wt % of the adhesive alloy powder.

In one embodiment of the present invention, the tin-based material contains 0-5 wt % Ag, 0-4 wt % Cu, 0-8 wt % Zn, 0-2 wt % In and 0.1-5 wt % of the bonding enhancement element, and the remaining is Sn.

In one embodiment of the present invention, the bismuth-based material contains 0-45 wt % Sn, 0-2 wt % in, 0-5 wt % Ag, 0-3 wt % Cu, 0-3 wt % Zn and 0.1-5 wt % of the bonding enhancement element, and the remaining is Bi.

In one embodiment of the present invention, the indium-based material contains 0-60 wt % Sn, 0-1 wt % Bi, 0-3 wt % Ag, 0-3 wt % Cu, 0-3 wt % Zn and 0.1-5 wt % of the bonding enhancement element, and the remaining is In.

In one embodiment of the present invention, the zinc-based material contains 1-5 wt % Al, 0-6 wt % Cu, 0-5 wt % Mg, 0-3 wt % Ag, 0-2 wt % Sn and 0.1-5 wt % of the bonding enhancement element, and the remaining is the Zn.

In one embodiment of the present invention, the adhesive alloy powder further comprises one material selected from the group consisting of Ga, Ge, Si, and a mixture thereof, and the material has a weight percentage ranged from 0.02 to 0.3 wt % of the adhesive alloy powder.

In one embodiment of the present invention, the adhesive alloy powder further comprises one material selected from the group consisting of up to 2.0 wt % Li, up to 5 wt % Sb, and a mixture thereof.

In one embodiment of the present invention, the adhesive alloy powder further comprises one material selected from the group consisting of P, Ni, Co, Mn, Fe, Cr, Al, Sr and a mixture thereof, and the material has a weight percentage ranged from 0.01 to 0.5 wt % of the adhesive alloy powder.

In one embodiment of the present invention, a weight ratio of the copper-containing conductive powder to the adhesive alloy powder is up to 9.

In one embodiment of the present invention, a particle diameter of the copper-containing conductive powder is 0.02-20 μm, and a particle diameter of the adhesive alloy powder is 0.02-20 μm.

In one embodiment of the present invention, the organic carrier is at least one organic additive selected from the group consisting of an adhesive agent, an organic solvent, a surfactant, a thickener, a flux, a thixotropic agent, a stabilizer, and a protective agent.

In one embodiment of the present invention, the conductive paste composition further comprises one material selected from the group consisting of sol-gel metals, metallo-organic compounds, and a mixture thereof, and the material has a weight percentage up to 10 wt % of the conductive paste composition.

In addition, the present invention provides a method of producing a conductive structure, comprising steps of: (a) providing a substrate and a conductive paste composition mentioned above; (b) applying the conductive paste composition onto the substrate to form a conductive pattern; (c) heating the conductive pattern; and (d) allowing the conductive pattern to be cooled down to form a conductive structure.

In one embodiment of the present invention, the substrate is selected from Al₂O₃, AlN, BN, Sapphire, GaAs, SiC, SiN, graphite, diamond like carbon, diamond, an aluminum substrate with ceramic layers, or a solar cell silicon substrate.

In one embodiment of the present invention, the step (c) further comprises a step of allowing the conductive pattern to be reflowed and applied an ultrasonic vibration thereto.

Furthermore, the present invention provides a conductive structure which comprises a substrate; and a conductive pattern containing a plurality of copper-containing conductive particles and an adhesive alloy selected from a tin-based alloy, a bismuth-based alloy, an indium-based alloy or a zinc-based alloy, wherein at least one part of the copper-containing conductive particles connect with each other through the adhesive alloy.

In one embodiment of the present invention, a weight ratio of the copper-containing conductive particles to the adhesive alloy is 7:3.

In one embodiment of the present invention, the copper-containing conductive particles comprises: (1) Cu; and (2) one material selected from the group consisting of Ag, Ni, Al, Pt, Fe, Pd, Ru, Ir, Ti, Co, a Pd—Ag alloy and a silver-based alloy, or a mixture of the material.

In one embodiment of the present invention, a contact surface between the copper-containing conductive particles and the adhesive alloy has a transitional phase metal layer.

In one embodiment of the present invention, the copper-containing conductive particles further comprises at least one element selected from the group consisting of 0.1-12 wt % Si, 0.1-10 wt % Bi, 0.1-10 wt % In, 0.1-0.5 wt % P and a mixture thereof.

### DESCRIPTION OF THE DRAWINGS

FIG. 1 is a cross-sectional view of the traditional solar cell.

FIG. 2 is a cross-sectional view of an electrode of a solar cell according to one embodiment of a conductive paste composition in the present invention.

FIG. 3 is an image taken by an electron microscope for showing the cross-section of the contact surface between the copper conductive paste and the solar cell chip.

FIGS. 4A and 4B are schematic views showing the formation of the electrode on the substrate.

### DETAILED DESCRIPTION OF THE PREFERRED EMBODIMENTS

The structure and the technical means adopted by the present invention to achieve the above and other objects can be best understood by referring to the following detailed description of the preferred embodiments. In addition, directional terms described by the present invention, such as upper, lower, front, back, left, right, inner, outer, side, etc., are only directions by referring to the accompanying drawings, and thus the directional terms are used to describe and understand the present invention, but the present invention is not limited thereto. Furthermore, if there is no specific description in the invention, singular terms such as “a”, “one”, and “the” include the plural number. For example, “a compound” or “at least one compound” may include a plurality of compounds, and the mixtures thereof. If there is no specific description in the invention, “%” means “weight percentage (wt %)”, and the numerical range (e.g. 10%-11% of A) contains the upper and lower limit (i.e. 10%≦A≦11%). If the lower limit is not defined in the range (e.g. less than, or below 0.2% of B), it means that the lower limit is 0 (i.e. 0%≦B≦0.2%). The proportion of “weight percent” of each component can be replaced by the proportion of “weight portion” thereof. The abovementioned terms are used to describe and understand the present invention, but the present invention is not limited thereto.

One embodiment of the present invention is to provide a conductive paste composition which comprises a copper-containing conductive powder; an adhesive alloy powder; and an organic carrier. The organic carrier is 5-35 wt % by weight of the conductive paste composition. A conductive structure can be formed on a substrate by using the conductive paste composition.

The conductive paste composition described herein contains the adhesive alloy powder which can accelerate the combination of the copper-containing conductive powder with each other, and an electrode with a substrate. In the conductive paste composition of the present invention, the conductive powder is a metal powder or an alloy powder which forms an electrode to be as a conductive layer with a main function of transferring electrons. In one embodiment, the conductivity is measured by a Four Point Sheet Resistance Meter; the antioxidation temperature is analyzed by TGA (Thermogravimetric Analysis), and the composition is analyzed by ICP-MS (Inductively Coupled Plasma Mass Spectrometry). The conductive powder has a conductivity over 5.00×10⁶ S(Siemens)/m at 20° C. In one embodiment, the conductive powder is selected from a group consisting of Cu (5.82×10⁷ S/m), Ag (6.19×10⁷ S/m), Ni (1.52×10⁷ S/m), Al (3.75×10⁷ S/m), Pt (9.72×10⁶ S/m), Fe (1.01×10⁷ S/m), Pd (5.82×10⁷ S/m), Ru (3.22×10⁷ S/m), Ir (2.01×10⁷ S/m), Ti (2.82×10⁷ S/m), Co (1.47×10⁷ S/m), an Ag—Pd alloy (5.01×10⁷ S/m), a copper-based alloy (5.42×10⁷ S/m), a silver-based alloy (5.65×10⁷ S/m), and an alloy or a mixture thereof. In one embodiment of the present invention, the copper-containing conductive powder further comprises at least one element selected from the group consisting of 0.1-12 wt % Si, 0.1-10 wt % Bi, 0.1-10 wt % In, 0.05-1 wt % P and a mixture thereof, which is able to slow down the oxidation of the copper-containing conductive powder. For example, the silicon content of the copper-containing conductive powder in the present invention is preferably 1-6 wt % for better anti-oxidation, and 2-3.5 wt % is more preferable. When the copper-containing conductive powder has 2.5 wt % Si (Cu2.5Si alloy), the anti-oxidation temperature is raised up to 253° C., which is much higher than 151° C. of the pure copper in the comparative example; When the contained Si exceeds 8 wt %, the high anti-oxidation will damage the conductivity. In addition, the copper-containing conductive powder has better anti-oxidation when the content of indium is 1-3 wt %, which is capable of solution into the copper-containing conductive powder. The copper-containing conductive powder having 1.5 wt % In (Cu1.5In alloy) has an anti-oxidation temperature of 255° C. Furthermore, the bismuth content of the copper-containing conductive powder is preferably 0.5-2.5 wt %, thereby the bismuth is capable of being aggregated near the grain boundary of the particles of copper-containing conductive powder and the anti-oxidation property is improved. When the copper-containing conductive powder has 2 wt % Bi, the anti-oxidation temperature can be reached to 273° C. Moreover, the P content of the copper-containing conductive powder in the present invention is preferably 0.1-0.3 wt %, thereby the phosphor is uniformly dispersed therein; when the content exceeds 0.6 wt %, the phosphor will aggregate on the surface layer so that the conductivity and the follow-up application are damaged.

A method for producing the conductive powder or the copper-containing conductive powder according to the present invention can be performed by general electrolysis, chemical reduction, atomization, mechanical comminuting process, or vapor-deposition, but it is not limited thereto.

Furthermore, the copper-containing conductive powder can be covered thereon a protective layer. The protective layer is selected from the group consisting of Au with a thickness ranged from 0.1 to 2 μm, Ag with a thickness ranged from 0.2 to 3 μm, Sn with a thickness ranged from 1 to 5 μm, Ni with a thickness ranged from 0.5 to 5 μm, a Ni/P alloy with a thickness ranged from 1 to 5 μm, a Ni—Pd—Au alloy with a thickness ranged from 1 to 3 μm and a combination thereof in any stacked order, so that the oxidation of the copper-containing conductive powder can be further slowed, and the combination between the copper-containing conductive powder is improved during firing to further improve the conductivity of the formed electrode. For example, the copper-containing conductive powder covered by a layer of Au (Au/Cu alloy) can achieve an excellent anti-oxidation with a thickness ranged from 0.1 to 0.5 μm in a cost concern, the anti-oxidation temperature can be reached to 240-310° C. In addition, the copper-containing conductive powder covered by a layer of Ag (Ag/Cu alloy) can achieve a high anti-oxidation with a thickness ranged from 0.4 to 2 μm, the anti-oxidation temperature can be reached to 210-295° C.; the copper-containing conductive powder covered by a layer of Sn (Sn/Cu alloy) can achieve a high anti-oxidation and no damage to the conductivity with a thickness ranged from 1 to 2.5 μm, but will cause damage with a thickness over 2.5 μm; the copper-containing conductive powder covered by a layer of Ni, Ni—P alloy or Ni—Pd—Au alloy can achieve a better anti-oxidation with a thickness ranged from 1 to 2 μm. From above, the conductive powder is a copper-based alloy, a mixture, or a copper powder covered by other metal layers, but it is not limited thereto. The conductive powder or the copper-containing conductive powder with an antioxidant metal layer thereon can be provided by electrolysis, electroless, sputtering, and coating, but it is not limited thereto.

The adhesive alloy powder of the conductive paste composition described herein can accelerate the combination of the conductive powders, and the combination of the electrode and the substrate. The adhesive alloy powder comprises the composition listed in Table 1 to Table 4, but it is not limited thereto. In the conductive paste composition of the present invention, the adhesive alloy powder can be a tin-based material, a bismuth-based material, an indium-based material, or a zinc-based material, as shown in Tables 1-4, and the solidus temperature and the liquidus temperature are measured by DSC (Differential Scanning Calorimetry).

As shown in Table 1, the tin-based material contains 0-5 wt % Ag, 0-4 wt % Cu, 0-8 wt % Zn, 0-2 wt % In, 0.1-5 wt % of the bonding enhancement element (PBE) comprising 0-3.5 wt % Ti group and 0.1-1.5 wt % rare earth group, and a remaining wt % of Sn to reach 100 wt %. In an embodiment S-1, the adhesive alloy powder comprises 0.3 wt % Ag, 0.5 wt % Cu, 1 wt % Li, 0.3 wt % Ge, 2.2 wt % of the bonding enhancement element, and the remaining wt % of Sn. The bonding enhancement element contains 2 wt % Ti and 0.2 wt % La series mixing rare earth (RE); and the La series mixing rare earth contains 73 wt % Ce, 11.1 wt % La, 14.9 wt % Pr, and 2 wt % other La series rare earth elements. In the embodiment S-1, 1 wt % Li can decrease the solidus and liquidus temperature about 2° C., reduce the use of Ti, and improve the combination of the adhesive alloy on the Al₂O₃ and AlN substrate. In addition, the composition of each batch of the mixing rare earth is different but the function thereof is not influenced. The composition of the mixing rare earth is not limited, and the mixing rare earth is cheap and easy to obtain relative to the pure rare earth element. In further embodiment S-5, the tin-based adhesive alloy powder contains 0.15 wt % In, 0.3 wt % Ag, 0.7 wt % Cu, 4.5 wt % Sb, 0.25 wt % Li and 3.1 wt % of the bonding enhancement element, and the remaining wt % of Sn. The bonding enhancement element contains 3 wt % Ti and 0.1 wt % La series mixing rare earth. The 4.5 wt % Sb in the embodiment S-5 can increase the solidus and liquidus temperature of the tin-based adhesive alloy to 237° C. and 245° C. respectively, and improve the surface property of the substrate, improve the reaction between the bonding enhancement element and the substrate so as to improve the combination. In addition, the 0.15 wt % In can increase the combination between the tin-based adhesive alloy powder and the conductive metal powder or ceramic substrate when the tin-based adhesive alloy powder is melted.

TABLE 1

| | | tin-based | | | | | | |
|---|---|---|---|---|---|---|---|---|
| element/group | | | | | | | | Comparative |
| (wt %) | | S-1 | S-2 | S-3 | S-4 | S-5 | SR-1 | example 2 |
| Sn | | Bal. | Bal. | Bal. | Bal. | Bal. | Bal. | Bal. |
| Bi | | — | — | 3 | — | — | 0-3 | — |
| In | | — | — | 1 | 0.2 | 0.15 | 0-2 | — |
| Ag | | 0.3 | 0.5 | 0.5 | 3 | 0.3 | 0-5 | 3.5 |
| Cu | | 0.5 | 4 | 0.7 | 0.5 | 0.7 | 0-4 | — |
| Zn | | — | — | 8 | — | — | 0-8 | — |
| Sb | | — | 0.5 | 1.5 | 1.2 | 4.5 | 0-5 | — |
| Li | | 1 | — | 0.5 | 0.2 | 0.25 | 0-2 | — |
| Ga, Ge, etc. | | 0.3Ge | 0.2Ga | — | — | — | 0-0.3 | — |
| Bonding | Ti, Zr etc. | 2Ti | 1.2Zr | — | 2Ti | 3Ti | 0-3.5 | |
| enhancement | RE | 0.2RE | 0.2La | 1.5RE | 0.2RE | 0.1RE | 0.1-1.5 | — |
| element | | | | | | | | |
| Solidus temp. ° C. | | 228 | 216 | 190 | 218 | 237 | 190-228 | 221 |
| Liquidus temp. ° C. | | 236 | 222 | 200 | 223 | 245 | 200-245 | 223 |
| Conductivity (×10⁶ S/m) | | 8.7 | 11.4 | 10.4 | 10.1 | 9.2 | 8.7-11.4 | 11.2 |
| Combination | Metallic | ⊚ | ⊚ | ⊚ | ⊚ | ⊚ | ⊚ | ⊚ |
| property | substrate | | | | | | | |
| | Hardly | ⊚ | ⊚ | ⊚ | ⊚ | ⊚ | ⊚ | X |
| | wettable | | | | | | | |
| | substrate | | | | | | | |

⊚: fully combined
Δ: partially combined
X: non-combined

Furthermore, as shown in table 2, the bismuth-based material contains 0-45 wt % Sn, 0-2 wt % In, 0-5 wt % Ag, 0-3 wt % Cu, 0-1.5 wt % Sb, 0-3 wt % Zn, 0-2 wt % Li, 0.1-5 wt % of the bonding enhancement element comprising 0-3.5 wt % Ti group and 0.1-1.5 wt % rare earth group, and a remaining wt % of Bi to reach 100 wt %. In addition, preferably, the bismuth-based adhesive alloy powder contains 42 wt % Sn, 0.2 wt % In, 0.5 wt % Ag, 0.7 wt % Cu, 0.5 wt % Sb, 1 wt % Li, 0.1 wt % Ge, 1 wt % of the bonding enhancement element, and the remaining wt % of Bi. The 0.1 wt % Ge can increase the combination between the bismuth-based adhesive alloy powder and the conductive metal powder when the bismuth-based adhesive alloy powder is melted.

TABLE 2

| | | bismuth-based | | | | | | |
|---|---|---|---|---|---|---|---|---|
| element/group | | | | | | | | Comparative |
| (wt %) | | B-1 | B-2 | B-3 | B-4 | B-5 | BR-1 | example 1 |
| Sn | | 41 | 41 | 41 | 42 | 42 | 0-45 | 42 |
| Bi | | Bal. | Bal. | Bal. | Bal. | Bal. | Bal. | Bal. |
| In | | — | — | — | 0.2 | 1 | 0-2 | — |
| Ag | | 0.3 | 0.3 | 0.3 | 0.5 | 0 | 0-5 | — |
| Cu | | 0.7 | 0.7 | 0.7 | 0.7 | 3 | 0-3 | — |
| Zn | | — | — | — | — | 1 | 0-3 | — |
| Sb | | — | — | — | 0.5 | 5 | 0-5 | — |
| Li | | — | — | 0.2 | 1 | 1.2 | 0.2 | — |
| Ga, Ge etc. | | — | — | — | 0.1Ge | 0.1Ga | 0-0.3 | — |
| Bonding | Ti, Zr etc. | 3Ti | 3.5Ti | — | — | 0-3.5 | — | |
| enhancement | RE | | 0.2Ce | 1.5RE | 1RE | 0.1-1.5 | — | — |
| element | | | | | | | | |
| Solidus tamp. ° C. | | 139 | 140 | 139 | 138 | 285 | 139-285 | 138 |
| Liquidus temp. ° C. | | 143 | 144 | 143 | 145 | 306 | 143-306 | 140 |
| Conductivity (×10⁶ S/m) | | 4.2 | 4.3 | 4.3 | 4.3 | 1.2 | 1.2-4.3 | 3.8 |
| Combination | Metallic | ⊚ | ⊚ | ⊚ | ⊚ | ⊚ | ⊚ | ⊚ |
| property | substrate | | | | | | | |
| | Hardly | Δ | Δ | ⊚ | ⊚ | ⊚ | ⊚ | X |
| | wettable | | | | | | | |
| | substrate | | | | | | | |

⊚: fully combined
Δ: partially combined
X: non-combined

Furthermore, as shown in Table 3, the indium-based material contains 0-60 wt % Sn, 0-1 wt % Bi, 0-3 wt % Ag, 0-3 wt % Cu, 0-3 wt % Zn, 0-3 wt % Sb, 0-2 wt % Li, 0.1-5 wt % of the bonding enhancement element comprising 0-3.5 wt % Ti group and 0.1-1.5 wt % rare earth group, and a remaining wt % of in to reach 100 wt %. In another embodiment 1-1, the bismuth-based material contains 3 wt % Ag, 0.5 wt % Cu, 0.2 wt % Li, 2.6 wt % of the bonding enhancement element comprising 2.5 wt % Ti and 0.1 wt % of the mixing rare earth, and the remaining wt % of In to 100 wt %. The 3 wt % Ag can increase conductivity and reduce melting point relative to the conductivity of 11.6×10⁶ S/m and the melting point of 156.6° C. of the pure In. In addition, the small amount of Ag₂In particles precipitated in the bismuth-based adhesive alloy can increase the mechanical strength; adding 0.5 wt % Cu can achieve the same result. The bonding enhancement element (Ti) is capable of solution in the indium-based material to form small amount of Ti₂In₅ particles. The preferred embodiment 1-3 shows the indium-based adhesive alloy powder contains 48 wt % Sn, 0.2 wt % Bi, 1.0 wt % Ag, 0.5 wt % Cu, 1.5 wt % Sb, 0.3 wt % Li, 0.1 wt % Ge, 3.15 wt % of the bonding enhancement element comprising 3 wt % Ti and 0.15 wt % of the mixing rare earth, and the remaining wt % of In. The embodiment 1-1 to 1-3 show superior combination properties.

TABLE 3

| | | indium-based | | | | |
|---|---|---|---|---|---|---|
| | | | | | | Com- |
| element/group | | | | | | parative |
| (wt %) | | I-1 | I-2 | I-3 | IR-2 | example 3 |
| Sn | | — | — | 48 | 0-60 | 49 |
| Bi | | — | — | 0.2 | 0-1 | Bal. |
| In | | Bal. | Bal. | Bal. | Bal. | |
| Ag | | 3 | — | 1 | 0-3 | — |
| Cu | | 0.5 | 3 | 0.5 | 0-3 | — |
| Zn | | — | 1 | — | 0-3 | — |
| Sb | | — | 3 | 1.5 | 0-5 | — |
| Li | | 0.2 | 0.5 | 0.3 | 0-2 | — |
| Ga, Ge etc. | | — | — | 0.1Ge | 0-0.3 | — |
| Bonding | 2.5Ti | — | 3Ti | 0-3.5 | | 1.2Ti |
| enhancement | 0.1RE | 1.2Pr | 0.15RE | 0.1-1.5 | | — |
| element | | | | | | |
| Solidus temp. ° C. | | 143 | 154 | 119 | 122-154 | 119 |
| Liquidus temp. ° C. | | 149 | 160 | 123 | 128-160 | 122 |
| Conductivity | | 12.6 | 13.2 | 10.2 | 10.2-13.2 | 10.6 |
| (×10⁶ S/m) | | | | | | |
| Combination | Metallic | ⊚ | ⊚ | ⊚ | ⊚ | ⊚ |
| property | sub- | | | | | |
| | strate | | | | | |
| | Hardly | ⊚ | ⊚ | ⊚ | ⊚ | X |
| | wettable | | | | | |
| | sub- | | | | | |
| | strate | | | | | |

⊚: fully combined
Δ: partially combined
X: non-combined

Furthermore, in one embodiment, the zinc-based material contains 1-5 wt % Al, 0-6 wt % Cu, 0-5 wt % Mg, 0-2 wt % Li, 0-2 wt % Sn, 0-3 wt % Ag, 0-3 wt % Sb, 0-0.2 wt % Ga, 0.1-5 wt % of the bonding enhancement element comprising 0-3.5 wt % of Ti group and 0.1-1.5 wt % of rare earth group, and a remaining wt % of Zn to 100 wt %. As shown in Table 4, in an embodiment Z-2, the added 3 wt % Cu can effectively improve the conductivity and reduce solidus/liquidus temperature to 343° C./359° C. In a further embodiment, the 4 wt % Mg and 2 wt % Li in the adhesive alloy powder of the preferred embodiment Z-3 can reduce the solidus/liquidus temperature to 338° C./346° C. relative to the solidus/liquidus temperature in the comparative example 4 to 381.9° C./385° C. The adhesive alloy powder of the present invention can be provided by atomization, mechanical comminuting process, vapor-deposition, chemical reduction, or electrolysis, but it is not limited thereto.

TABLE 4

| | | zinc-based | | | | |
|---|---|---|---|---|---|---|
| element/group | | | | | Com- | |
| (wt %) | | | | | parative | |
| Z-1 | | Z-2 | Z-3 | ZR-1 | example 4 | |
| Zn | | Bal. | Bal. | Bal. | Bal. | Bal. |
| Al | | 3 | 5 | 4 | 1-5 | 4 |
| Cu | | — | 3 | 0.7 | 0-6 | — |
| Mg | | — | 1 | 4 | 0-5 | — |
| Li | | — | 0.5 | 2 | 0-2 | — |
| Sn, In, Bi etc. | | — | — | 1 | 0-2 | — |
| Ag | | 0.3 | 0.3 | 0.3 | 0-3 | — |
| Sb | | 0.2 | — | 1 | 0-5 | — |
| Ga, Ge, Si etc | | 0.1Ge | 0.2Ga | 0.2Si | 0-0.2 | — |
| Bonding | Ti, Zr | 2Ti | 3Ti | 2Ti | 0-3.5 | — |
| enhancement | etc. | | | | | |
| element | RE | 0.15RE | — | 0.1RE | 0.1-1.5 | — |

| Solidus temp. ° C. | | 382 | 343 | 338 | 343-382 | 381.9 |
|---|---|---|---|---|---|---|
| Liquidus temp. ° C. | | 388 | 359 | 346 | 359-388 | 385 |
| Conductivity (×10⁶ S/m) | | 14.5 | 16.2 | 15.2 | 14.5-15.2 | 13.2 |
| Combination | ⊚ | ⊚ | ⊚ | ⊚ | Δ | |
| property | Hardly | ⊚ | ⊚ | ⊚ | ⊚ | X |
| Metallic | wettable | | | | | |
| substrate | sub- | | | | | |
| | strate | | | | | |

⊚: fully combined
Δ: partially combined
X: non-combined

In one embodiment, the adhesive alloy powder further comprises at least one bonding enhancement element selected from the group consisting of Ti, V, Zr, Hf, Nb, Ta, Mg, rare earth elements and a mixture thereof, and the bonding enhancement element is below 4 wt % relative to the adhesive alloy powder. The rare earth elements can be selected from the group consisting of Y, Sc, La series and a mixture thereof, and has a weight percentage ranged from 0.1 to 2 wt % relative to the adhesive alloy powder. According to one embodiment, in atmosphere at a heating temperature of 170° C., the oxidation of the bismuth-based adhesive alloy powder having 0.1-1.2 wt % Ti in the embodiment B-1 is slow, and the combination is better to the conductive powder or the conductive metallic substrate. However, the combination is poor for the hardly wettable substrate and cannot form a success combination. The hardly wettable substrate is for example AlN, SiC, SiNx, Al₂O₃, BN, TiO₂, ZrO₂, Y₂O₃, silicon chips, GaAs chips, graphite, diamond like carbon, and diamond. In another embodiment, in atmosphere at a heating temperature of 170° C., the oxidation of the bismuth-based adhesive alloy powder having 3 wt % Ti in the embodiment B-2 is very fast, and the combination is poor to the conductive powder or the conductive metallic substrate, and it is also poor for the hardly wettable substrate. The bismuth-based adhesive alloy powder in embodiment B-3 further comprises 0.2 wt % rare earth element Ce and 3.5 wt % Ti, which can slow down the oxidation in atmosphere, and has excellent combination with the conductive powder and the hardly wettable substrate. Further, concerning cost and complex problems of purifying the rare earth elements, the La series mixing rare earth is preferable. In another embodiment, the amount of the non-rare earth elements can be reduced by adding 1-1.5 wt % La series mixing rare earth in the adhesive alloy powder, such as Ti, V, Zr groups. In addition, in a further embodiment, the bismuth adhesive alloy powder having 1.2 wt % Li in the embodiment B-5 performs a good combination with the conductive powder and the hardly wettable substrate and can reduce the amount of the Ti group or the rare earth element in the bonding enhancement element.

The adhesive alloy powder further comprises Ge, Ga, P, Si or a mixture thereof, and has a weight percentage ranged from 0.02 to 0.3 wt % relative to the adhesive alloy powder, which can increase wettability. For example, by X-ray photoelectron spectroscopy (XPS), the adhesive alloy powder containing 0.025 wt % Ga element forms an extra-thin oxidation film on its surface to protect the adhesive alloy powder from oxidation after melting, and improve the wettability of the adhesive alloy powder. In another embodiment, the adhesive alloy powder further comprises 0-5 wt % Sb for accelerating the reaction of the adhesive alloy powder and the hardly wettable substrate to form an extra-thin metalized layer of a Sb-rich IMC after the adhesive alloy powder is melted.

In one embodiment, the adhesive alloy powder can further comprises Ni, Co, Mn, Fe, Cr, Al, Sr or a mixture thereof, and has a weight percentage ranged from 0.01 to 0.5 wt % relative to the adhesive alloy powder for further fining the crystalline grain size.

Furthermore, in the conductive paste composition of the present invention, the mixture of the conductive powder and the adhesive alloy powder is called a function metal mixture (FMM). The weight ratio of the copper-containing conductive powder to the adhesive alloy powder in the FMM is 0-9:10-1, such as 0:1, 0.5:9.5, 1:9, 2:8, 3:7, 4:6, 5:5, 6:4, 7:3, or 4:1, and more preferably 7:3 because the conductivity of the formed electrode is good and combination is also good to the substrate, but it is not limited thereto. The size of the powder in the present invention is analyzed by a laser diffraction scattering particle size analyzer. In one embodiment, the copper-containing conductive powder has an average particle size (d₅₀) ranged from 0.02 to 50 μm substantially, and preferably from 0.5 to 10 μm. The adhesive alloy powder has an average particle size (d₅₀) substantially ranged from 0.02 to 50 μm, and preferably from 0.3 to 5 μm. The conductive powder and the adhesive alloy powder can be ball-shaped, sheet-shaped, stick-shaped, or irregular shape. In one embodiment, the ball-shaped powder is preferable so that the conductive paste composition has a better dispersion. The FMM according to the present invention further comprises 0-10 wt % sol-gel metals (SGM) and metallo-organic compounds (MOC) or a mixture thereof so as to increase the density of the electrode and the conductivity. The conductive sol-gel metals can be Au, Ag, Cu, Ni, Pt, Pd, Sn, Bi, In, or a mixture thereof, and it is not limited thereto. In addition, the conductive metal contained in the sol-gel metals can be 1-80 1-80 wt %, more preferably 25-60 wt %, but it is not limited thereto. In one embodiment, the FMM comprises 10 wt % sol-gel Ag containing 30 wt % Ag, 45 wt % copper-containing conductive powder, and 40 wt % of the bismuth-based adhesive alloy powder in the embodiment B-5, and 5 wt % organic carrier is then added thereto. After mixing for 5 hours, the mixture is fired for 250 seconds at 175° C. The combination strength can be increased to 12% and the conductivity can be improved to 8%. In addition, the metallo-organic compounds can be AgO₂C(CH₂OCH₂)₃H, Cu(C₇H₁₅COO), Bi(C₇H₁₅COO), Ti(CH₃O)₂(C₉H₁₉COO), or a mixture thereof, but it is not limited thereto. In another embodiment, the FMM comprises 5 wt % AgO₂C(CH₂OCH₂)₃H, 43 wt % copper-containing conductive powder, and 40 wt % of the indium-based adhesive alloy powder in the embodiment 1-2, and 12 wt % organic carrier is then added thereto. After mixing for 5 hours, the mixture is fired for 250 seconds at 145° C. The combination strength can be increased to 6% and the conductivity can be improved to 5%.

The conductive paste composition described herein comprises an organic carrier. The organic carrier can be formed by at least one organic additive or organic solvent. In one embodiment, the organic additive can be resins (e.g. phenol resins, phenolic resins, epoxy resins), cellulose derivatives (e.g. ethyl cellulose ethoce), rosin derivatives (e.g. hydrogenated rosin, wood rosin), terpineol, abietinol, ethylene glycol monobutyl ether, texanol, polymethylacrylate, polyester, polycarbonate, poly urethane, phosphate ester or a combination thereof, but it is not limited thereto. The organic solvent can be ethanol, acetone, isopropyl alcohol, glycerol, or an organic liquid. In one embodiment, the organic carrier has a preferred solvent amount ranged from 70 to 98 wt %.

For forming the conductive paste composition, the known preparing technology can be carried out. The method for forming the conductive paste composition is not critical as long as the FMM can be uniformly dispersed in the organic carrier. In one embodiment, the FMM and the organic carrier are mixed by a three-roller mixer for 3-24 hours to form a homogenous mixture. The formed composition having viscosity is called “paste”, and has rheological properties suitable for printing and spraying. If the organic carrier has a high viscosity, a solvent can be added therein to adjust the viscosity. In one embodiment, a weight ratio of the organic carrier to the FMM can be 5-35:95-65, such as 5:95, 10:90, 15:85, 20:80, 25:85, 30:70, or 35:65, more preferably 10:90, but it is not limited thereto. Furthermore, the organic carrier further comprises an additive selected from the group consisting of a surfactant, a thickener, a flux, a thixotropic agent, a stabilizer, a protective agent, and a mixture thereof. The amount of the additive is defined by the industry and the desired property when using the conductive paste, and it is not limited in the present invention.

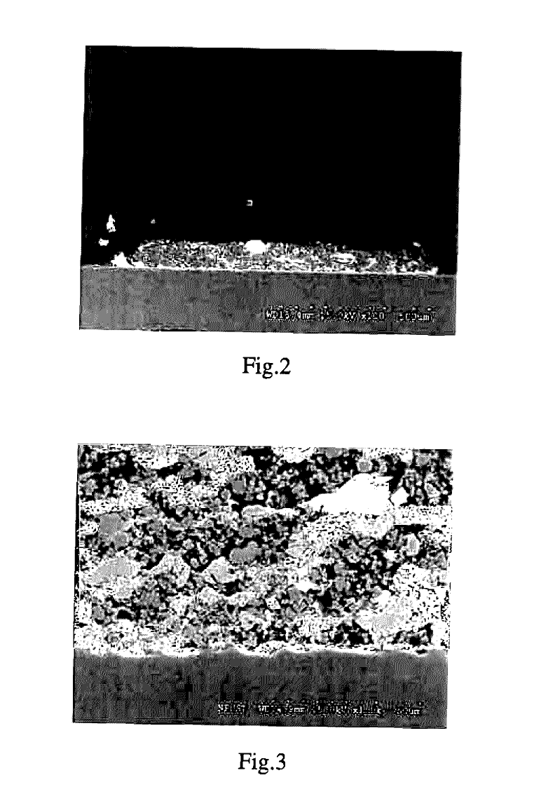

A second embodiment of the present invention is to provide a method of producing a conductive structure, mainly comprising steps of (S1) providing a substrate and a conductive paste composition as mentioned above; (S2) applying the conductive paste composition onto the substrate to form a conductive pattern; (S3) heating the conductive pattern; and (S4) allowing the conductive pattern to be cooled down to form a conductive structure. The step (S3) further comprises a step of allowing the conductive pattern to be reflowed and applied an ultrasonic disturbance thereto, so as to assist the melted adhesive alloy in the conductive paste composition to connect the conductive powder with each other and combine to the substrate. The frequency of the ultrasonic disturbance can be 20-120 KHz, but it is not limited thereto. In one embodiment, the activation of the adhesive alloy in the conductive paste composition can be enhanced under the ultrasonic disturbance, and the connection on the surface of the copper-containing conductive powder with the melted adhesive alloy is also accelerated as well as the thermal oxidation of the copper-containing powder during firing process can be prevented. Another function is to accelerate a combining reaction of the bonding enhancement element of the melted adhesive alloy with the surface of the substrate. First, a silicon chip used for a solar cell is provided with a passivation layer (also known as the Anti-Reflection Coating, ARC). Silica (SiOx), silicon nitride (SiNx), titanium oxide (TiOx), aluminum oxide (Al₂O₃), tantalum oxide (Ta₂O₅), indium tin oxide (ITO) or silicon carbide (SiCx) can be used as a material of the passivation layer. In one embodiment, the conductive paste composition comprising 90 wt % of the FMM and 10 wt % of the organic carrier is formed after mechanical mixing. As the embodiments shown in Table 5, the conductive paste composition is applied on a front side (n-type doped emitter) of the silicon chip of the solar cell by screen printing. Next, the chip is dried at a rate of 60-80° C./min for 2 minutes. The dried pattern is fired in an IR heater with an ultrasonic disturbance in air. The maximum temperature is 150-450° C. and the processing time is 120 seconds. In the embodiment P-1, the conductive paste composition comprises 90 wt % of the adhesive alloy powder in the embodiment B-1 and 10 wt % of the organic carrier, and has the conductivity around 6.35×10⁶ S/m after reflowing and firing. In another embodiment P-4, the conductive paste composition comprises 90 wt % of the FMM and 10 wt % of the organic carrier, wherein the FMM containing 65 wt % of the copper-containing conductive powder and 25 wt % of the adhesive alloy powder in the embodiment B-1. The conductivity can be improved to 14.2×10⁶ S/m after reflowing and firing. FIG. 2 is a cross-sectional view of the electrode formed on the silicon chip of the solar cell according to the embodiment P-4.

In the embodiment P-6, the conductive paste composition contains 2 wt % AgO₂C(CH₂OCH₂)₃H which is able to improve the conductivity to 35.3×10⁶ S/m; in the embodiment P-8, the organic carrier included in the conductive paste composition contains epoxy resins so that the combination strength after firing can be improved to 5% (relative to the conductive paste composition without epoxy resins); in the embodiment P-9, the conductive paste composition comprising 10 wt % sol-gel Ag has the conductivity further improved to 25.1×10⁶ S/m. The formed structure is observed with an electron microscope and shown in FIG. 3.

TABLE 5

| | FMM (wt %) | | | | | |
|---|---|---|---|---|---|---|
| | | adhesive | | | Firing | |
| | conductive | alloy | Conductive additive | Organic carrier | Temp. | Conductivity |
| Group | powder | powder | (wt %) | (wt %) | (° C.) | (×10⁶ S/m) |
| P-1 | 0 | 90 wt % | — | hydrogenated | 175 | 6.35 |
| | | B-1 | | rosin + abietinol + ethanol | | |
| | | | | (10 wt %) | | |
| P-2 | 30 wt % Cu | 60 wt % | — | hydrogenated | 175 | 7.55 |
| | | B-1 | | rosin + abietinol + ethanol | | |
| | | | | (10 wt %) | | |
| P-3 | 50 wt % Cu | 40 wt % | hydrogenated | 175 | 9.29 | |
| | | B-1 | rosin + abietinol + ethanol | | | |
| | | | (10 wt %) | | | |
| P-4 | 65 wt % Cu | 25 wt % | — | hydrogenated | 175 | 14.2 |
| | | B-1 | | rosin + abietinol + ethanol | | |
| | | | | (10 wt %) | | |
| P-5 | 63 wt % Cu | 25 wt % | AgO₂C(CH₂OCH₂)₃H | hydrogenated | 175 | 31.2 |
| | | S-1 | (2 wt %) | rosin + abietinol + ethanol | | |
| | | | | (10 wt %) | | |
| P-6 | 63 wt | 25 wt % | AgO₂C(CH₂OCH₂)₃H | hydrogenated | 150 | 35.3 |
| | % Cu2Bi | I-3 | (2 wt %) | rosin + abietinol + ethanol | | |
| | | | | (10 wt %) | | |
| P-7 | 40 wt | 30 wt % | — | hydrogenated | 400 | 21.3 |
| | % Cu + 30 wt | Z-2 | | rosin + abietinol + ethanol | | |
| | % Ag | | | (10 wt %) | | |
| P-8 | 63 wt % Cu | 25 wt % | AgO₂C(CH₂OCH₂)₃H | hydrogenated | 175 | 36.2 |
| | | B-1 | (2 wt %) | rosin + abietinol + epoxy | | |
| | | | | resin + ethanol | | |
| | | | | (10 wt %) | | |
| P-9 | 57 wt % Cu | 25 wt % | sol-gel silver | hydrogenated | 175 | 23.1 |
| | | B-1 | (10 wt %) | rosin + abietinol + ethanol | | |
| | | | | (8 wt %) | | |

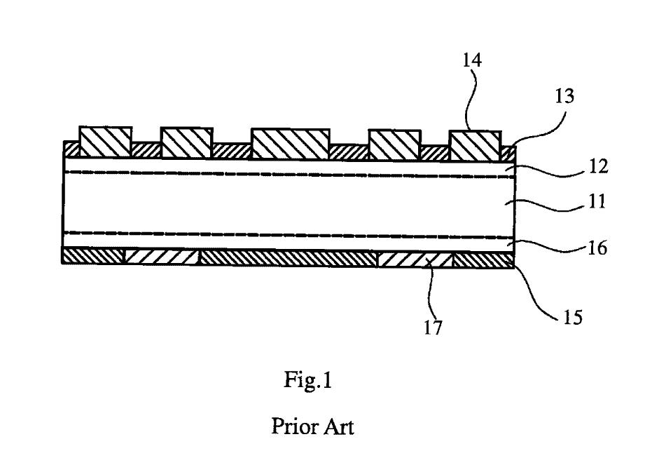

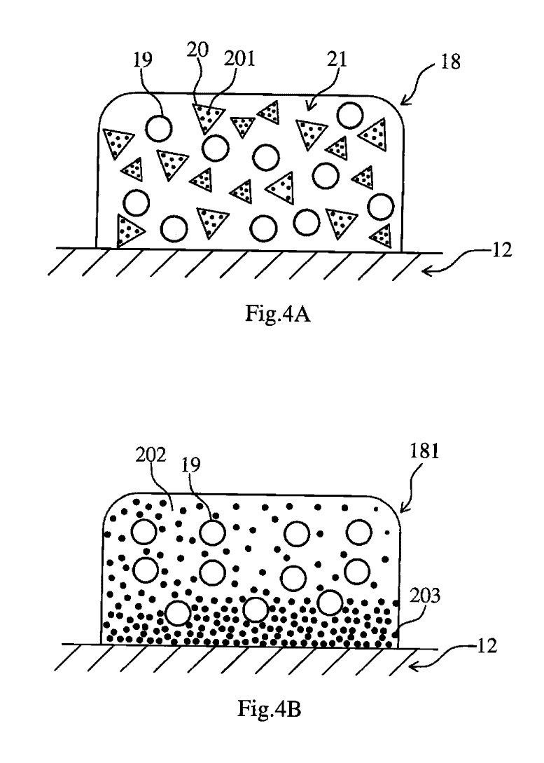

Referring to FIG. 1 and FIGS. 4A-4B, the adhesive alloy powder 20 in the conductive paste composition 18 can be melted to form the adhesive alloy 202. One part of the melted adhesive alloy 202 covers the conductive metal powder 19 during firing and then connects the conductive metal powder 19 with each other to form an electrode or a wire 17, another part of the melted adhesive alloy goes down to the surface of the substrate and combines to the substrate. The adhesive alloy 202 contains the bonding enhancement element 201 able to react with the substrate 12 to form a thin metalized layer of a transitional reaction layer 203. In a further analysis, the bonding enhancement element 11 of the adhesive alloy can reduce the passivation layer SiO₂ of the n-type solar cell to form silicon and a transitional reaction layer near the interface, but it is not limited thereto. The composition of the transitional reaction layer is determined by the conductive paste composition and the substrate, and the function thereof is not influenced by the composition. In a further embodiment, the conductive paste composition contains other bonding enhancement element (such as V, Nb) has the same reaction property of the connecting reaction with the passivation of the silicon solar cell. The conductive paste of the present invention is successfully applied to the electrode connection on the hardly wettable substrate, a metalized layer formed on the ceramic substrate, a corrosion protective layer on the metal material, the connection of the heat spreader, an electric assembly, a photoelectron assembly, a chip assembly, and the connection of a ceramic with a hardly wettable metal material, such as graphite, DLC, W—Cu, Ti, Al, Mg, Ta, W, and stainless steel.

In another embodiment, the step (S2) and (S3) can be combined into one step, that is, to heat and apply the conductive paste composition onto the substrate simultaneously. For example, a step of directly heating a nozzle of a printing machine while printing to achieve the purpose of heating and coating at the same time. It is also possible to pre-heat the substrate before applying the conductive paste composition thereon, so that the substrate has a predetermined temperature below 450° C., for example 150-250° C., thereby the combination of the conductive paste composition and the substrate is improved, the organic carrier in the conductive paste composition is removed, and the thermal deformation or warpage of the substrate can be avoided. In a further embodiment, an ultrasonic disturbance can be applied to the substrate while heating and printing. The frequency of the ultrasonic disturbance is 20-60 KHz, but it is not limited thereto. Furthermore, in one embodiment, the substrate can be Al₂O₃, AlN, BN, Sapphire, GaAs, SiC, SiN, graphite, diamond like carbon (DLC), diamond, an aluminum substrate with ceramic layers, or a solar cell silicon substrate, and the conductive paste composition can be applied on these substrate to form a conductive structure. The conductive structure as shown in FIG. 1 can be a front electrode 14 or a rear electrode 15, but it is not limited thereto.

Therefore, a third embodiment of the present invention is to provide a conductive structure, comprising: a substrate; and a conductive pattern containing a plurality of copper-containing conductive particles and an adhesive alloy. A part of the copper-containing conductive particles can be connected with each other through the adhesive alloy, and another part of the copper-containing conductive particles can be connected with the substrate through the adhesive alloy so as to form a layer of a transition metal layer. The adhesive alloy is formed by heating the adhesive alloy powder. The adhesive alloy can be a tin-based alloy, a bismuth-based alloy, an indium-based alloy, or a zinc-based alloy. The tin-based alloy contains 0-5 wt % Ag, 0-4 wt % Cu, 0-8 wt % Zn, 0-2 wt % In, 0.1-5 wt % of the bonding enhancement element comprising 0-3.5 wt % of Ti group and 0.1-1.5 wt % of rare earth group, and a remaining wt % of Sn. The bismuth-based alloy contains 0-45 wt % Sn, 0-2 wt % In, 0-5 wt % Ag, 0-3 wt % Cu, 0-3 wt % Zn, 0.1-5 wt % of the bonding enhancement element comprising 0-3.5 wt % of Ti group and 0.1-1.5 wt % of rare earth group, and a remaining wt % of Bi. The indium-based alloy contains 0-60 wt % Sn, 0-1 wt % Bi, 0-3 wt % Ag, 0-3 wt % Cu, 0-3 wt % Zn, 0.1-5 wt % of the bonding enhancement element comprising 0-3.5 wt % of Ti group and 0.1-1.5 wt % of rare earth group, and a remaining wt % of In. The zinc-based alloy contains 1-5 wt % Al, 0-6 wt % Cu, 0-5 wt % Mg, 0-3 wt % Ag, 0-2 wt % Sn, 0.1-5 wt % of the bonding enhancement element comprising 0-3.5 wt % of Ti group and 0.1-1.5 wt % of rare earth group, and a remaining wt % of the Zn. A weight ratio of the copper-containing conductive particles to the adhesive alloy is 7:3. The copper-containing conductive particles comprises Cu and one material selected from the group consisting of Ag, Ni, Al, Pt, Fe, Pd, Ru, Ir, Ti, Co, a Pd—Ag alloy, a silver-based alloy, and an alloy thereof. The copper-containing conductive particles further comprises at least one element selected from the group consisting of 0.1-12 wt % Si, 0.1-10 wt % Bi, 0.1-10 wt % In, 0.1-0.5 wt % P and a mixture thereof. The copper-containing conductive particles further comprises a protective layer selected from the group consisting of Au with a thickness ranged from 0.1 to 2 μm, Ag with a thickness ranged from 0.2 to 3 μm, Sn with a thickness ranged from 1 to 5 μm, Ni with a thickness ranged from 0.5 to 5 μm, a Ni/P alloy with a thickness ranged from 1 to 5 μm, a Ni—Pd—Au alloy with a thickness ranged from 1 to 3 μm and a combination thereof.

Compared with the current technology, the conductive paste composition, the conductive structure and the method of producing the conductive structure according to the present invention perform electric conduction at a relatively lower temperature to solve the problem of thermal deformation. In addition, the used of the copper-containing conductive powder to replace the traditional silver-based conductive paste material as the based material and the use of adhesive alloy powder having conductivity to replace the glass particles without conductivity not only reduce the material costs, but also improve the conductivity of the conductive structure.

The present invention has been described with preferred embodiments thereof and it is understood that many changes and modifications to the described embodiments can be carried out without departing from the scope and the spirit of the invention that is intended to be limited only by the appended claims.

What is claimed is:

1. A conductive paste composition, comprising:
(a) a copper-containing conductive powder;
(b) an adhesive alloy powder selected from a tin-based material, a bismuth-based material, an indium-based material or a zinc-based material; and
(c) an organic carrier which is 5-35% by weight of the conductive paste composition.

2. The conductive paste composition according to claim 1, wherein the copper-containing conductive powder comprises (1) Cu; and (2) one material selected from the group consisting of Ag, Ni, Al, Pt, Fe, Pd/Ru, Ir, Ti, Co, an Ag/Pd alloy, a copper-based alloy and a silver-based alloy, or a mixture of the material.

3. The conductive paste composition according to claim 2, wherein the copper-containing conductive powder further comprises at least one element selected from the group consisting of 0.1-12 wt % Si, 0.1-10 wt % Bi, 0.1-10 wt % In, 0.05-1 wt % P, and a mixture thereof.

4. The conductive paste composition according to claim 2, wherein the copper-containing conductive powder further comprises a protective layer selected from the group consisting of Au with a thickness ranged from 0.1 to 2 μm, Ag with a thickness ranged from 0.2 to 3 μm, Sn with a thickness ranged from 1 to 5 μm, Ni with a thickness ranged from 0.5 to 5 μm, a Ni/P alloy with a thickness ranged from 1 to 5 μm, a Ni—Pd—Au alloy with a thickness ranged from 1 to 3 μm and a combination thereof.

5. The conductive paste composition according to claim 1, wherein the adhesive alloy powder further comprises at least one bonding enhancement element selected from the group consisting of Ti, V, Zr, Hf, Nb, Ta, Mg, rare earth elements and a mixture thereof, and the bonding enhancement element is below 5% of the adhesive alloy powder.

6. The conductive paste composition according to claim 5, wherein the rare earth elements is selected from the group consisting of Y, Sc, La series and a mixture thereof, and has a weight percentage ranged from 0.1 to 1.5% of the adhesive alloy powder.

7. The conductive paste composition according to claim 5, wherein the tin-based material contains 0-5 wt % Ag, 0-4 wt % Cu, 0-8 wt % Zn, 0-2 wt % In and 0.1-5 wt % of the bonding enhancement element, and the remaining is Sn.

8. The conductive paste composition according to claim 5, wherein the bismuth-based material contains 0-45 wt % Sn, 0-2 wt % In, 0-5 wt % Ag, 0-3 wt % Cu, 0-3 wt % Zn and 0.1-5 wt % of the bonding enhancement element, and the remaining is Bi.

9. The conductive paste composition according to claim 5, wherein the indium-based material contains 0-60 wt % Sn, 0-1 wt % Bi, 0-3 wt % Ag, 0-3 wt % Cu, 0-3 wt % Zn and 0.1-5 wt % of the bonding enhancement element, and the remaining is In.

10. The conductive paste composition according to claim 5, wherein the zinc-based material contains 1-5 wt % Al, 0-6 wt % Cu, 0-5 wt % Mg, 0-3 wt % Ag, 0-2 wt % Sn and 0.1-5 wt % of the bonding enhancement element, and the remaining is the Zn.

11. The conductive paste composition according to claim 1, wherein the adhesive alloy powder further comprises one material selected from the group consisting of Ga, Ge, Si, and a mixture thereof, and the material has a weight percentage ranged from 0.02 to 0.3 wt % of the adhesive alloy powder.

12. The conductive paste composition according to claim 1, wherein the adhesive alloy powder further comprises one material selected from the group consisting of up to 2.0 wt % Li, up to 5 wt % Sb, and a mixture thereof.

13. The conductive paste composition according to claim 1, wherein the adhesive alloy powder further comprises one material selected from the group consisting of P, Ni, Co, Mn, Fe, Cr, Al, Sr and a mixture thereof, and the material has a weight percentage ranged from 0.01 to 0.5 wt % of the adhesive alloy powder.

14. The conductive paste composition according to claim 1, wherein a weight ratio of the copper-containing conductive powder to the adhesive alloy powder is up to 9.

15. The conductive paste composition according to claim 1, wherein a particle diameter of the copper-containing conductive powder is 0.02-20 μm, and a particle diameter of the adhesive alloy powder is 0.02-20 μm.

16. The conductive paste composition according to claim 1, wherein the organic carrier is at least one organic additive selected from the group consisting of an adhesive agent, an organic solvent, a surfactant, a thickener, a flux, a thixotropic agent, a stabilizer, and a protective agent.

17. The conductive paste composition according to claim 1, wherein the conductive paste composition further comprises one material selected from the group consisting of sol-gel metals, metallo-organic compounds, and a mixture thereof, and the material has a weight percentage up to 10 wt % of the conductive paste composition.

18. A method of producing a conductive structure, comprising steps of:
(a) providing a substrate and a conductive paste composition according to claim 1;
(b) applying the conductive paste composition onto the substrate to form a conductive pattern;
(c) heating the conductive pattern; and
(d) allowing the conductive pattern to be cooled down to form a conductive structure.

19. The method according to claim 18, wherein the substrate is selected from Al₂O₃, AlN, BN, Sapphire, GaAs, SiC, SiN, graphite, diamond like carbon, diamond, an aluminum substrate with a ceramic layer, or a solar cell silicon substrate.

20. The method according to claim 18, wherein the step (c) further comprises a step of allowing the conductive pattern to be reflowed and applied an ultrasonic vibration thereto.

21. A conductive structure, comprising:
a substrate; and
a conductive pattern containing a plurality of copper-containing conductive particles and an adhesive alloy selected from a tin-based alloy, a bismuth-based alloy, an indium-based alloy or a zinc-based alloy, wherein at least one part of the copper-containing conductive particles connect with each other through the adhesive alloy.

22. The conductive structure according to claim 21, wherein a weight ratio of the copper-containing conductive particles to the adhesive alloy is 7:3.

23. The conductive structure according to claim 21, wherein the copper-containing conductive particles comprises: (1) Cu; and (2) one material selected from the group consisting of Ag, Ni, Al, Pt, Fe, Pd, Ru, Ir, Ti, Co, a Pd—Ag alloy and a silver-based alloy, or a mixture of the material.

24. The conductive structure according to claim 21, wherein a contact surface between the copper-containing conductive particles and the adhesive alloy has a transitional phase metal layer.

25. The conductive structure according to claim 21, wherein the copper-containing conductive particles further comprises at least one element selected from the group consisting of 0.1-12 wt % Si, 0.1-10 wt % Bi, 0.1-10 wt % In, 0.1-0.5 wt % P and a mixture thereof.
